(19) United States
(12) Patent Application Publication
(10) Pub. No.: US 2019/0131483 A1
(43) Pub. Date: May 2, 2019

(54) SOLAR CONTROL FILM AND MANUFACTURING METHOD THEREOF

(71) Applicant: Institute of Nuclear Energy Research, Atomic Energy Council, Executive Yuan, R.O.C, Taoyuan (TW)

(72) Inventors: EN-SHIH CHEN, Taoyuan (TW); Tzong-Daw Wu, Taoyuan (TW); Cheng-Chang Hsieh, Taoyuan (TW); Ching-Pei Tseng, Taoyuan (TW); Yung-Ching Liu, Taoyuan (TW)

(21) Appl. No.: 16/038,516

(22) Filed: Jul. 18, 2018

(30) Foreign Application Priority Data
Oct. 26, 2017 (TW) 106136976

(51) Int. Cl. H01L 31/18; H01L 21/02; C23C 16/40; H01L 23/29; C03C 17/23; C03C 17/34

(52) U.S. Cl. CPC H01L 31/18; H01L 21/02521; C03C 17/3417; H01L 23/291; C03C 17/23; C23C 16/40

(57) ABSTRACT

A method for manufacturing a solar control film includes: a step of applying an arc-plasma coating process to deposit a first dielectric layer on a soft substrate, the first dielectric layer containing Ti; a step of depositing a first metal layer on the first dielectric layer; a step of applying the arc-plasma coating process to deposit a second dielectric layer on the first metal layer, the second dielectric layer containing the Ti; a step of depositing a second metal layer on the second dielectric layer; and, a step of applying the arc-plasma coating process to deposit a third dielectric layer on the second metal layer, the third dielectric layer containing the Ti. In addition, a solar control film is also provided.

### CROSS REFERENCE TO RELATED APPLICATION

This application claims the benefit of Taiwan Patent Application Serial No. 106136976, filed on Oct. 26, 2017, the subject matter of which is incorporated herein by reference.

### BACKGROUND OF THE INVENTION

### (1) Field of the Invention

The invention relates to a solar control film and a method for manufacturing the solar control film, and more particularly to the solar control film and the method for manufacturing the solar control film that apply an arc-plasma coating process to form dielectric layers for the solar control film.

### (2) Description of the Prior Art

For a purpose of shading sunshine or reducing load of indoor air-conditioner, proper sun-shading tools are usually applied to windows of constructions or transportation vehicles. These sun-shading tools include various shutters, curtains, thermal-insulated papers and the like sun or solar control films. Generally, to obtain successful sun shading, trade-off shall be made between lightness and thermal insulation. It is easy to understand that indoor illumination from daylights would become poor while the sunshine is shaded for any kind of purposes or tools. On the other hand, for indoor lighting to be benefited from the sunshine, rising of the interior temperature would be inevitable.

Recently, an infrared reflective solar control film is introduced to serve a better sun-shading job. However, since the sputtering process used for forming the dielectric layer needs a special material indium (In), and the In is one of staple goods generally protected by its source country, thus the sourcing of the In usually forms a problem. In addition, while in applying the sputtering process, a poisoning effect usually occurs at a target of a metal oxide. Thus, monitoring this poisoning effect becomes important during the sputtering process, and thus the entire manufacturing difficulty would be raised. In generally, the usage of the target in the sputtering process is in a range of about 20˜30%, from which the whole production efficiency would be reduced.

Hence, the topic of providing a solar control film and a method for manufacturing the solar control film to overcome the aforesaid production problem is definitely urgent and important to the skill in the art.

### SUMMARY

Accordingly, it is an object of the present invention to provide a solar control film and a method for manufacturing the solar control film, that can implement the targets more efficiently, reduce the replacement frequency of the targets, lower the production cost, simplify the production complexity, and improve the production efficiency. The solar control film produced in accordance with the present invention can be applied to windows of constructions and vehicles.

In the present invention, the method for manufacturing a solar control film includes: a step of applying an arc-plasma coating process to deposit a first dielectric layer on a soft substrate, the first dielectric layer containing Ti; a step of depositing a first metal layer on the first dielectric layer; a step of applying the arc-plasma coating process to deposit a second dielectric layer on the first metal layer, the second dielectric layer containing the Ti; a step of depositing a second metal layer on the second dielectric layer; and, a step of applying the arc-plasma coating process to deposit a third dielectric layer on the second metal layer, the third dielectric layer containing the Ti.

In one embodiment of the present invention, a step of using a transparent soft material for packaging is further included.

In one embodiment of the present invention, before the arc-plasma coating process to deposit the first dielectric layer, the method for manufacturing a solar control film further includes: a step of providing the soft substrate; a step of displacing the soft substrate into a chamber of an arc-plasma coating apparatus; a step of vacuuming the chamber; and, a step of introducing an oxygen into the chamber.

In one embodiment of the present invention, the first metal layer contains Ag, and the second metal layer contains also the Ag.

In one embodiment of the present invention, after the first metal layer is deposited on the first dielectric layer, the method for manufacturing a solar control film further includes a step of depositing a first protective layer on the first metal layer so as to sandwich the first protective layer between the first metal layer and the second dielectric layer.

In one embodiment of the present invention, the first protective layer contains the Ti.

In one embodiment of the present invention, after the second metal layer is deposited on the second dielectric layer, the method for manufacturing a solar control film further includes a step of depositing a second protective layer on the second metal layer so as to sandwich the second protective layer between the second metal layer and the third dielectric layer.

In one embodiment of the present invention, the second protective layer contains the Ti.

In another aspect of the present invention, the method for manufacturing a solar control film includes: a step of applying an arc-plasma coating process to deposit a first dielectric layer on a soft substrate, the first dielectric layer containing Ti; a step of applying the arc-plasma coating process to deposit a first conductive layer on the first dielectric layer; and, a step of applying the arc-plasma coating process to deposit a second dielectric layer on the first conductive layer, the second dielectric layer containing the Ti.

In one embodiment of the present invention, the method further includes a step of using a transparent soft material for packaging.

In one embodiment of the present invention, before the arc-plasma coating process to deposit the first dielectric layer, the method further includes: a step of providing the soft substrate; a step of displacing the soft substrate into a chamber of an arc-plasma coating apparatus; a step of vacuuming the chamber; and, a step of introducing an oxygen into the chamber.

In one embodiment of the present invention, the first conductive layer contains the TiN.

In one embodiment of the present invention, the step of applying the arc-plasma coating process to deposit the second dielectric layer on the first conductive layer includes: a step of applying the arc-plasma coating process to deposit a second conductive layer on the second dielectric layer; and, a step of applying the arc-plasma coating process to deposit a third dielectric layer on the second conductive layer, the third dielectric layer containing the Ti.

In one embodiment of the present invention, the second conductive layer contains the TiN.

In a further aspect of the present invention, the solar control film includes a soft substrate, a first dielectric layer, a second dielectric layer, a second metal layer, a third dielectric layer and an encapsulated layer. The first dielectric layer disposed on the soft substrate is formed by an arc-plasma coating process, and contains Ti. The first metal layer is disposed on the first dielectric layer. The second dielectric layer disposed on the first metal layer is formed by the arc-plasma coating process, and contains the Ti. The second metal layer is disposed on the second dielectric layer. The third dielectric layer disposed on the second metal layer is formed by the arc-plasma coating process, and contains the Ti. The encapsulated layer is disposed on the third dielectric layer.

In one embodiment of the present invention, the first metal layer contains Ag, and the second metal layer contains also the Ag.

In one embodiment of the present invention, the solar control film further includes a first protective layer located between the first metal layer and the second dielectric layer, and a second protective layer located between the second metal layer and the third dielectric layer.

In one embodiment of the present invention, the first protective layer contains the Ti, and the second protective layer contains also the Ti.

In a furthermore aspect of the present invention, the solar control film includes a soft substrate, a first dielectric layer, a first conductive layer, a second dielectric layer and an encapsulated layer. The first dielectric layer disposed on the soft substrate is formed by an arc-plasma coating process, and contains Ti. The first conductive layer is disposed on the first dielectric layer. The second dielectric layer disposed on the first conductive layer is formed by the arc-plasma coating process, and contains the Ti. The encapsulated layer is disposed on the second dielectric layer.

In one embodiment of the present invention, the solar control film further includes a second conductive layer disposed on the second dielectric layer, and a third dielectric layer disposed on the second conductive layer. The third dielectric layer is formed by the arc-plasma coating process, and contains the Ti.

In one embodiment of the present invention, the first conductive layer contains TiN, and the second conductive layer contains the TiN.

In one embodiment of the present invention, the first conductive layer is formed by the arc-plasma coating process, and the second conductive layer is also formed by the arc-plasma coating process.

As described above, in comparison with the prior art that adopts a sputtering system to deposit the In-oxide dielectric layer, the solar control film and the method thereof provided by the present invention apply the arc-plasma coating process with lower cost but higher usage efficiency of coating targets to deposit the dielectric layers, and the material Ti is used to deposit the thin metal-oxide (TiO₂) films. Since the arc-plasma coating apparatus does not cost much relatively, and the usage efficiency of coating targets in the arc-plasma coating apparatus is usually better than that of conventional sputtering technique by 20%˜30%, thus the time for coating the film can be extended, the production can be faster, and the the respective production cost can be reduced.

Further, in comparison with the conventional infrared reflective solar control film that includes an In-oxide dielectric layer, since the indium (In) is widely and increasingly used in most of manufacturing processes in the electronic industry and hard to be obtained due to severe export policies of the source countries, the solar control film, the first dielectric layer of the present invention uses the common material Ti to form the thin metal-oxide (TiO₂) film, not the indium (In) to form the In-oxide dielectric layers.

Thereupon, the risk in material shortage of the indium can be avoided, and also the production cost can be substantially reduced.

In addition, by comparing to the conventional solar control film that includes a metal-oxide coating film produced by sputtering, since a poisoning effect usually occurs at a target of a metal oxide during the sputtering process, thus in-process monitoring of this poisoning effect becomes important, and thereby the entire manufacturing difficulty would be raised. On the other hand, the dielectric layer of the solar control film produced in accordance with the present invention are formed by applying the arc-plasma coating process, and thus aforesaid shortcomings of the prior art in both the poisoning effect and the manufacturing difficulty can be substantially resolved.

All these objects are achieved by the solar control film and the method for manufacturing the same solar control film described below.

### BRIEF DESCRIPTION OF THE DRAWINGS

The present invention will now be specified with reference to its preferred embodiment illustrated in the drawings, in which:

FIG. 1A is a schematic view of a first embodiment of the solar control film layer in accordance with the present invention;

FIG. 1B is a schematic view of a first embodiment of the solar control film in accordance with the present invention, having the solar control film layer of FIG. 1A;

FIG. 2A is a schematic view of a second embodiment of the solar control film layer in accordance with the present invention;

FIG. 2B is a schematic view of a second embodiment of the solar control film in accordance with the present invention, having the solar control film layer of FIG. 2A;

FIG. 3A is a schematic view of a third embodiment of the solar control film layer in accordance with the present invention;

FIG. 3B is a schematic view of a third embodiment of the solar control film in accordance with the present invention, having the solar control film layer of FIG. 3A;

FIG. 4 is a flowchart of a first embodiment of the method for manufacturing a solar control film in accordance with the present invention;

FIG. 5 is a flowchart of a second embodiment of the method for manufacturing a solar control film in accordance with the present invention;

FIG. 6 is a flowchart of a third embodiment of the method for manufacturing a solar control film in accordance with the present invention;

FIG. 7 is a schematic plot of a reflection spectrum for the solar control film layer of FIG. 1A;

FIG. 8 is a schematic plot of a reflection spectrum for the solar control film layer of FIG. 3A; and

FIG. 9 is a schematic plot of a reflection spectrum for the solar control film produced by the method of FIG. 6.

### DESCRIPTION OF THE PREFERRED EMBODIMENT

The invention disclosed herein is directed to a solar control film and a method for manufacturing the same solar control film. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

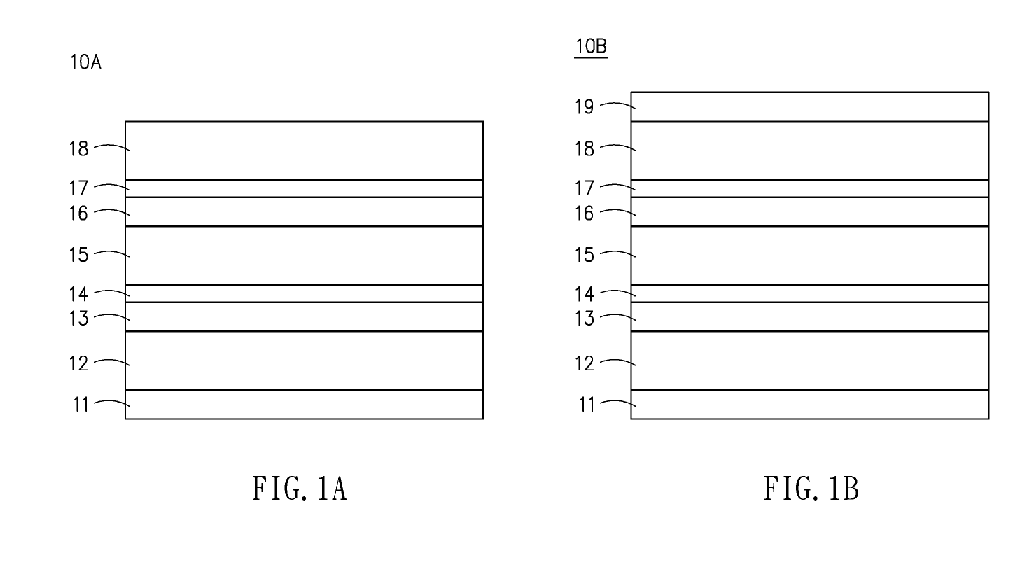

FIG. 1A is a schematic view of a first embodiment of the solar control film layer in accordance with the present invention, and FIG. 1B is a schematic view of a first embodiment of the solar control film having the solar control film layer of FIG. 1A. Referring firstly to FIG. 1A, in this embodiment, the solar control film layer 10A includes a soft substrate 11, a first dielectric layer 12, a first metal layer 13, a first protective layer 14, a second dielectric layer 15, a second metal layer 16, a second protective layer 17 and a third dielectric layer 18.

In this embodiment, the soft substrate 11 is made of polyethylene terephthalate (PET). The first dielectric layer 12 disposed on the soft substrate 11 contains titanium (Ti), and is deposited by an arc-plasma coating process, such that the first dielectric layer 12 is formed as a thin TiO₂ film (i.e., a thin metal-oxide film). In this embodiment, the first dielectric layer 12 has a thickness of 15˜70 nm. The first metal layer 13 disposed on the first dielectric layer 12 contains silver (Ag), and has a thickness of 10˜18 nm. The first protective layer 14 disposed on the first metal layer 13 is to protect the first metal layer 13 from being hurt by the following processes. The first protective layer 14 contains Ti, and has a thickness of 1˜3 nm.

In this embodiment, the second dielectric layer 15, disposed on the first metal layer 13 by sandwiching the first protective layer 14 between the first metal layer 13 and the second dielectric layer 15, contains Ti, and is deposited by an arc-plasma coating process, such that the second dielectric layer 15 is formed as a thin TiO₂ film (i.e., a thin metal-oxide film). Preferably, the second dielectric layer 15 has a thickness of 15˜70 nm. The second metal layer 16 disposed on the second dielectric layer 15, contains Ag, and has a thickness of 10˜18 nm. The second protective layer 17 disposed on the second metal layer 16 is to protect the second metal layer 16 from being hurt by the following processes. The second protective layer 17 contains Ti, and has a thickness of 1˜3 nm. The third dielectric layer 18, disposed on the second metal layer 16 by sandwiching the second protective layer 17 between the second metal layer 16 and the third dielectric layer 18, contains Ti, and is deposited by an arc-plasma coating process, such that the third dielectric layer 18 is formed as a thin TiO₂ film (i.e., a thin metal-oxide film) and has a thickness of 15˜70 nm. As shown in FIG. 1B, the solar control film layer 10A of FIG. 1A can be packaged by a transparent soft material. In this embodiment, an encapsulated layer 19 is disposed on the third dielectric layer 18 so as to form the solar control film 10B. The transparent soft material can be the polyethylene terephthalate (PET).

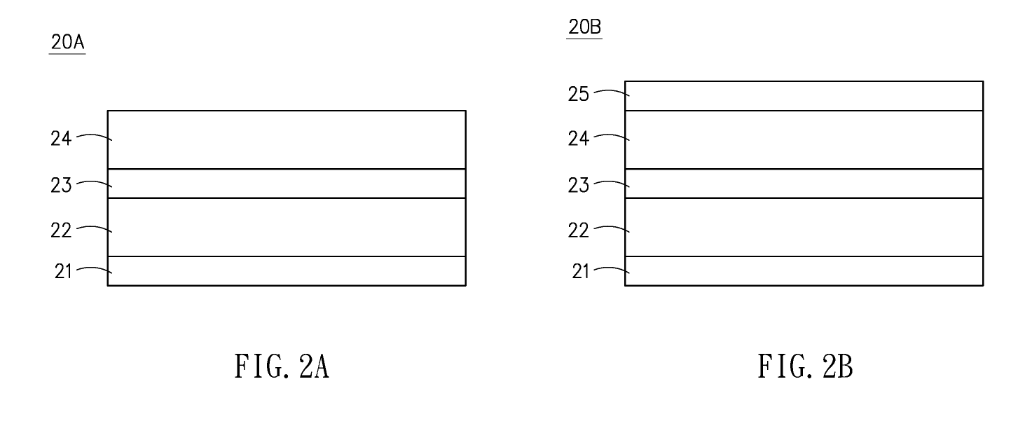

FIG. 2A is a schematic view of a second embodiment of the solar control film layer in accordance with the present invention, and FIG. 2B is a schematic view of a second embodiment of the solar control film having the solar control film layer of FIG. 2A. Referring now to FIG. 2A, in this embodiment, the solar control film layer 20A includes a soft substrate 21, a first dielectric layer 22, a first conductive layer 23 and a second dielectric layer 24.

In this embodiment, the soft substrate 21 is made of the polyethylene terephthalate (PET). The first dielectric layer 22 disposed on the soft substrate 21 contains Ti, and is deposited by an arc-plasma coating process, such that the first dielectric layer 22 is formed as a thin TiO₂ film (i.e., a thin metal-oxide film) with a thickness of 15˜70 nm. The first conductive layer 23 disposed on first dielectric layer 22 deposited by an arc-plasma coating process contains TiN, and has a thickness of 5˜30 nm. The second dielectric layer 24 disposed on the first conductive layer 23 contains Ti, and is deposited by an arc-plasma coating process, such that the second dielectric layer 24 is formed as a thin TiO₂ film (i.e., a thin metal-oxide film) with a thickness of 15˜70 nm. As shown in FIG. 2B, finally the resulted solar control film layer 20A is packaged by a transparent soft material. In this embodiment, an encapsulated layer 25 is formed on the second dielectric layer 24 so as to obtain the solar control film 20B. The transparent soft material can be the polyethylene terephthalate (PET).

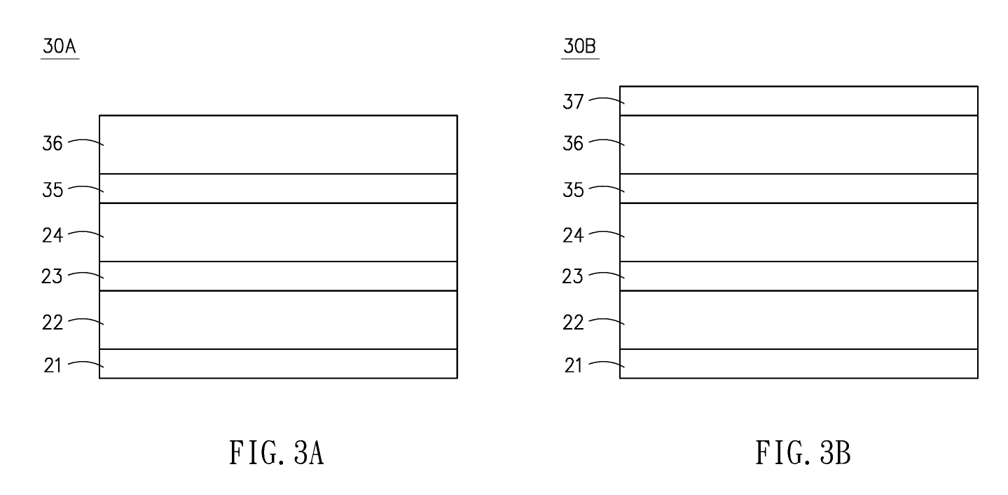

FIG. 3A is a schematic view of a third embodiment of the solar control film layer in accordance with the present invention, and FIG. 3B is a schematic view of a third embodiment of the solar control film having the solar control film layer of FIG. 3A. Referring now to FIG. 3A, it shall be declared firstly that the solar control film layer 30A of FIG. 3A is resembled to the solar control film layer 20A of FIG. 2B. In these two embodiments, the same elements would be assigned by the same number so as to indicate the same function they serve, but details thereabout would be omitted herein. Namely, in the following descriptions, only the differences in between are elucidated. As shown, the major difference between this embodiment of FIG. 3A and that of FIG. 2A is that, in this embodiment, the solar control film layer 30A further includes a second conductive layer 35 and a third dielectric layer 36.

In this embodiment, the second conductive layer 35 disposed on the second dielectric layer 24 is deposited by an arc-plasma coating process. In addition, the second conductive layer 35 contains TiN, and has a thickness of 5˜30 nm. The third dielectric layer 36 disposed on second conductive layer 35 contains Ti (Ti), and is deposited by an arc-plasma coating process, such that the third dielectric layer 36 is formed as a thin TiO₂ film (i.e., a thin metal-oxide film) with a thickness of 15˜70 nm. Finally, the solar control film layer 30A can be packaged by a transparent soft material. As shown, an encapsulated layer 37 is formed on the third dielectric layer 36 so as to form the solar control film 30B. In this embodiment, the transparent soft material can be made of polyethylene terephthalate (PET).

In comparison with the prior art that adopts a sputtering system to deposit the In-oxide dielectric layer, the solar control film 10, 20 or 30 as shown in FIG. 1A through FIG. 3B of the present invention can be provided with a lower cost. Since the arc-plasma coating process for producing the dielectric layers in the present invention is highly efficient, thus the dielectric layer formed by depositing Ti to result in a thin metal-oxide (TiO₂) film can be provided with a lower cost. In addition, since the usage efficiency of coating targets in the present invention is better than that of conventional sputtering technique, thus the production can be faster without increasing the respective production cost.

Further, in comparison with the conventional infrared reflective solar control film that includes an In-oxide dielectric layer, since the indium (In) is widely and increasingly used in most of manufacturing processes in the electronic industry and hard to be obtained due to severe export policies of the source countries, the material Ti used in the present invention for forming the thin metal-oxide (TiO₂) film is relatively common, and thus relevant to produce the replacement of the conventional In-oxide dielectric layer. Thereupon, the risk in material shortage for the indium that is used for forming the In-oxide dielectric layer can be avoided, and also the production cost can be substantially reduced.

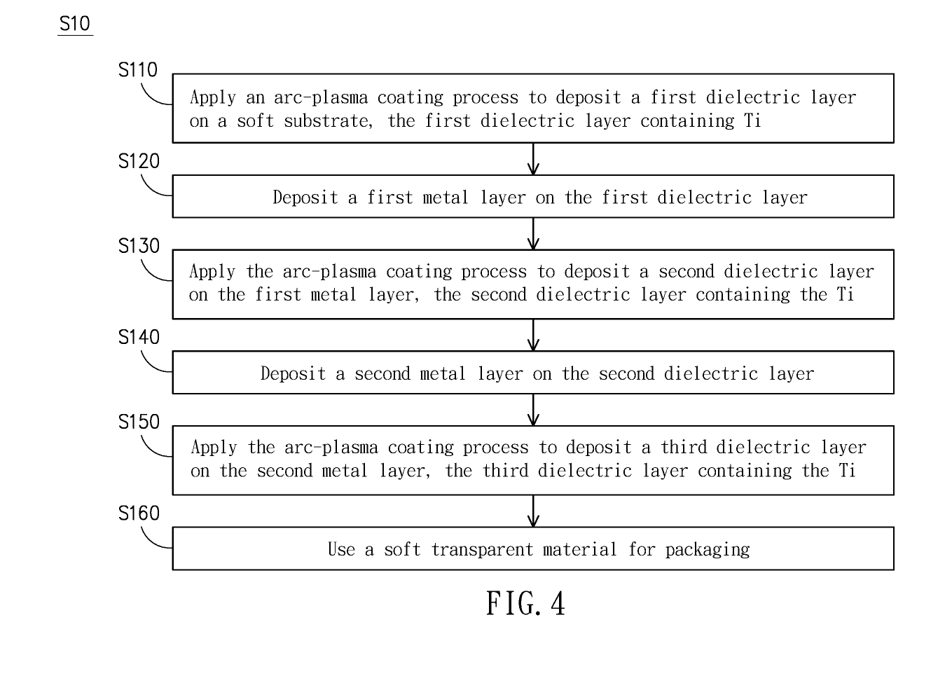

FIG. 4 is a flowchart of a first embodiment of the method for manufacturing a solar control film in accordance with the present invention. In this embodiment, the method for manufacturing a solar control film S10, particularly for forming the solar control film 10B of FIG. 1B, includes the following Step S110 through Step S160.

In Step S110, an arc-plasma coating process is applied to deposit a first dielectric layer 12 on a soft substrate 11, in which a material of the first dielectric layer 12 contains Ti. In details, firstly, the soft substrate 11 made of a polyethylene terephthalate (PET) is provided. The soft substrate 11 is displaced into a chamber of an arc-plasma coating apparatus, and then the chamber is vacuumed. As the chamber is vacuumed to a predetermined degree, an oxygen is introduced into the chamber. Then, the arc-plasma coating process is performed to deposit the first dielectric layer 12 onto the soft substrate 11, so that the first dielectric layer 12 as a thin metal-oxide (TiO₂) film is formed to have preferably a thickness of 15˜70 nm.

In Step S120, a first metal layer 13 is deposited on the first dielectric layer 12, in which the first metal layer 13 contains silver (Ag) and has a thickness of 10˜18 nm. After the first metal layer 13 is formed on the first dielectric layer 12, an optional step of depositing a first protective layer 14 on the first metal layer 13 can be performed, such that the first metal layer 13 can be protected from being hurt by the following processes. The first protective layer 14 contains Ti, and has a thickness of 1˜3 nm.

In Step S130, the arc-plasma coating process is applied to deposit a second dielectric layer 15 on the first metal layer 13. In the case that the first protective layer 14 exists, the second dielectric layer 15 is formed on the first protective layer 14. Namely, the first protective layer 14 is located between the first metal layer 13 and the second dielectric layer 15. The second dielectric layer 15 contains Ti, and is formed as a thin metal-oxide (TiO₂) film having preferably a thickness of 15˜70 nm.

In Step S140, a second metal layer 16 is deposited on the second dielectric layer 15. The second metal layer 16 contains Ag, and has a thickness of 10˜18 nm. After the second metal layer 16 is formed on the second dielectric layer 15, an optional step of depositing a second protective layer 17 on the second metal layer 16 can be performed, such that the second metal layer 16 can be protected from being hurt by the following processes. The second protective layer 17 contains Ti, and has a thickness of 1˜3 nm.

In Step S150, the arc-plasma coating process is applied to deposit a third dielectric layer 18 on the second metal layer 16. If the second protective layer 17 exists, then the third dielectric layer 18 is formed directly on the second protective layer 17. Namely, the second protective layer 17 is sandwiched between the third dielectric layer 18 and the second metal layer 16. The third dielectric layer 18 contains Ti, and is formed as a thin metal-oxide (TiO₂) film having preferably a thickness of 15˜70 nm. After performing Step S110˜Step S150, the solar control film layer 10A of FIG. 1A can be obtained.

Then, in Step S160, a soft transparent material is used to packaging the solar control film layer 10A of FIG. 1A. As shown in FIG. 1B, an encapsulated layer 19 is formed on the third dielectric layer 18 so as to form a solar control film 10B of FIG. 1B.

In comparison with the prior art that adopts a sputtering system to deposit the In-oxide dielectric layer, the solar control film 10B obtained by performing the aforesaid steps of the present invention applies the arc-plasma coating process to deposit the dielectric layers (including the first dielectric layer 12, the second dielectric layer 15 and the third dielectric layer 18). Since the arc-plasma coating apparatus does not cost much relatively, and the usage efficiency of coating targets in the arc-plasma coating apparatus is usually better than that of conventional sputtering technique, thus the production can be faster without increasing the respective production cost.

Further, in comparison with the conventional infrared reflective solar control film that includes an In-oxide dielectric layer, since the indium (In) is widely and increasingly used in most of manufacturing processes in the electronic industry and hard to be obtained due to severe export policies of the source countries, the solar control film 10B, the first dielectric layer 12, the second dielectric layer 15 and the third dielectric layer 18 of the present invention use the common material Ti to form the thin metal-oxide (TiO₂) film, not the indium (In) to form the In-oxide dielectric layers. Thereupon, the risk in material shortage of the indium can be avoided, and also the production cost can be substantially reduced.

In addition, by comparing to the conventional solar control film that includes a metal-oxide coating film produced by sputtering, since a poisoning effect usually occurs at a target of a metal oxide during the sputtering process, thus in-process monitoring of this poisoning effect becomes important, and thereby the entire manufacturing difficulty would be raised. On the other hand, the dielectric layers (including the first dielectric layer 12, the second dielectric layer 15 and the third dielectric layer 18) of the solar control film 10B produced in accordance with the present invention are formed by applying the arc-plasma coating processes, and thus aforesaid shortcomings of the prior art in both the poisoning effect and the manufacturing difficulty can be substantially resolved.

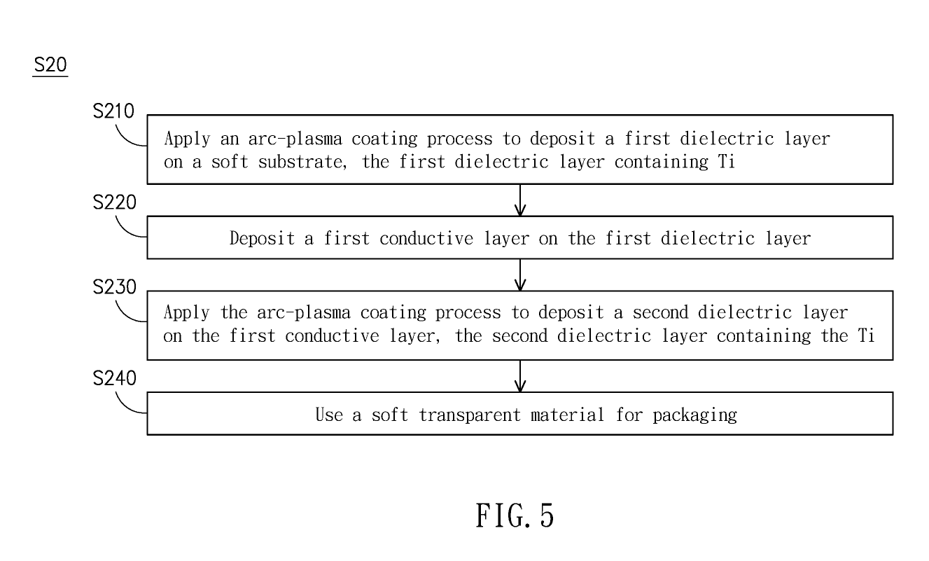

FIG. 5 is a flowchart of a second embodiment of the method for manufacturing a solar control film in accordance with the present invention. As shown, in this embodiment, the method for manufacturing a solar control film S20, particularly for forming the solar control film 20B of FIG. 2B, includes the following Step S210 through Step S240.

In Step S210, an arc-plasma coating process is applied to deposit a first dielectric layer 22 on a soft substrate 21, in which a material of the first dielectric layer 22 contains Ti. In details, firstly, the soft substrate 21 made of a polyethylene terephthalate (PET) is provided. The soft substrate 21 is displaced into a chamber of an arc-plasma coating apparatus, and then the chamber is vacuumed. As the chamber is vacuumed to a predetermined degree, an oxygen is introduced into the chamber. Then, the arc-plasma coating process is performed to deposit the first dielectric layer 22 onto the soft substrate 21, so that the first dielectric layer 22 as a thin metal-oxide (TiO₂) film is formed to have preferably a thickness of 15˜70 nm.

In Step S220, a first conductive layer 23 is deposited on the first dielectric layer 22, in which the first conductive layer 23 contains TiN and has a thickness of 5˜30 nm.

In Step S230, the arc-plasma coating process is applied to deposit a second dielectric layer 24 on the first conductive layer 23. The second dielectric layer 24 contains Ti, and is formed as a thin metal-oxide (TiO₂) film having preferably a thickness of 15˜70 nm. After performing Step S210˜Step S230, the solar control film layer 20A of FIG. 2A can be obtained. Then, in Step S240, a soft transparent material is used to packaging the solar control film layer 20A of FIG. 2A. As shown in FIG. 2B, an encapsulated layer 25 is formed on the second dielectric layer 24 so as to form a solar control film 20B of FIG. 2B.

In comparison with the prior art that adopts a sputtering system to deposit the In-oxide dielectric layer, the solar control film 20B obtained by performing the aforesaid steps of the present invention applies the arc-plasma coating process to deposit the dielectric layers (including the first dielectric layer 22 and the second dielectric layer 24). Since the arc-plasma coating apparatus does not cost much relatively, and the usage efficiency of coating targets in the arc-plasma coating apparatus is usually better than that of conventional sputtering technique, thus the production can be faster without increasing the respective production cost.

Further, in comparison with the conventional infrared reflective solar control film that includes an In-oxide dielectric layer, since the indium (In) is widely and increasingly used in most of manufacturing processes in the electronic industry and hard to be obtained due to severe export policies of the source countries, the solar control film 20B, the first dielectric layer 22 and the second dielectric layer 24 of the present invention use the common material Ti to form the thin metal-oxide (TiO₂) film, not the indium (In) to form the In-oxide dielectric layers. Thereupon, the risk in material shortage of the indium can be avoided, and also the production cost can be substantially reduced.

In addition, by comparing to the conventional solar control film that includes a metal-oxide coating film produced by sputtering, since a poisoning effect usually occurs at a target of a metal oxide during the sputtering process, thus in-process monitoring of this poisoning effect becomes important, and thereby the entire manufacturing difficulty would be raised. On the other hand, the dielectric layers (including the first dielectric layer 22 and the second dielectric layer 24) of the solar control film 20B produced in accordance with the present invention are formed by applying the arc-plasma coating processes, and thus aforesaid shortcomings of the prior art in both the poisoning effect and the manufacturing difficulty can be substantially resolved.

Furthermore, in the embodiment of FIG. 4, the metal layers and the dielectric layers are alternately laminated onto each other so as to achieve an effect of solar control. On the other hand, in the embodiment of FIG. 5, the conductive layers deposited by the arc-plasma coating processes are used to substitute the aforesaid metal layers for being alternately laminated to each other with the dielectric layers, such that the effect of solar control can be also obtained.

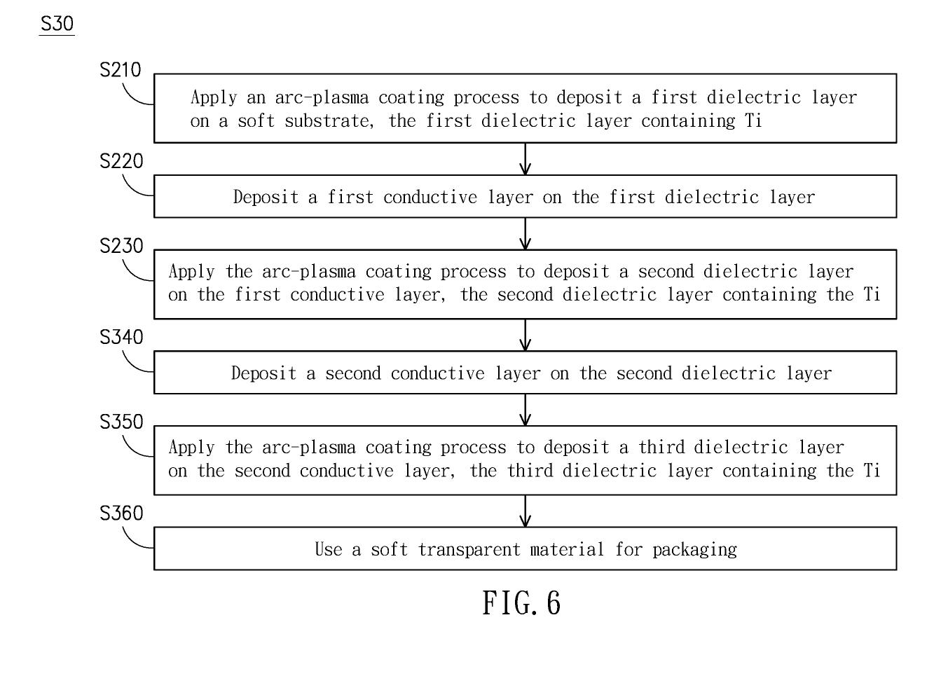

FIG. 6 is a flowchart of a third embodiment of the method for manufacturing a solar control film in accordance with the present invention. In this embodiment, the method for manufacturing a solar control film S30 is relevant to form the solar control film 30B of FIG. 3B. It shall be explained that the method for manufacturing a solar control film S30 of FIG. 6 is resembled to that S20 of FIG. 5. In these two embodiments, the same elements would be assigned by the same number so as to indicate the same function they serve, but details thereabout would be omitted herein. Namely, in the following descriptions, only the differences in between would be elucidated. The major difference between FIG. 6 and FIG. 5 is that, after Step S230 of the method for manufacturing a solar control film S30 of this embodiment is performed, Step S340 to Step S360 are further included. In Step S340, a second conductive layer 35 is deposited on the second dielectric layer 24. The second conductive layer 35 contains TiN, and has a thickness of 5˜30 nm. Then, in Step S350, the arc-plasma coating process is applied again to deposit a third dielectric layer 36 onto the second conductive layer 35. The third dielectric layer 36 contains Ti, so that the third dielectric layer 36 as a thin metal-oxide (TiO₂) film is formed to have preferably a thickness of 15˜70 nm. After performing Step S210˜Step S230 and Step S340˜Step S350, the solar control film layer 30A of FIG. 3A can be obtained. Then, in Step S360, a soft transparent material is used to packaging the solar control film layer 30A of FIG. 3A. As shown in FIG. 3B, an encapsulated layer 37 is formed on the third dielectric layer 36 so as to form a solar control film 30B of FIG. 3B.

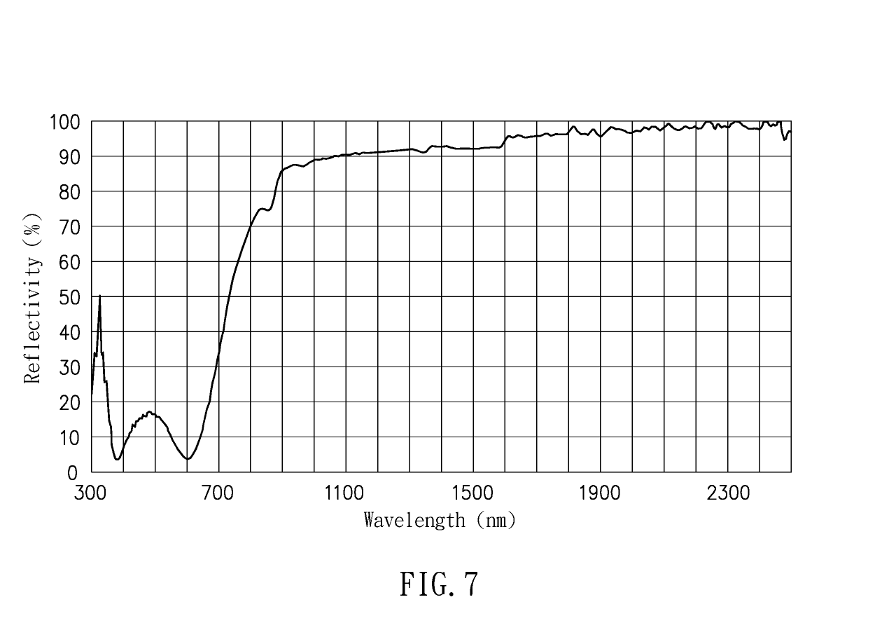

FIG. 7 is a schematic plot of a reflection spectrum for the solar control film layer of FIG. 1A. The horizontal axis of FIG. 7 stands for the wavelength, while the vertical axis thereof stands for the reflectivity. In this exemplary example, the solar control film layer 10A of FIG. 1A is taken to undergo a spectrum test. In this solar control film layer 10A, the first metal layer 13 and the second metal layer 16 are both conductive films. From the reflection spectrum shown in FIG. 7, the reflectivity is greater than 70% for the wavelengths within 800˜1000 nm, and the reflectivity is greater than 90% for the wavelengths within 1000˜2500 nm. It implies that the solar control film layer 10A of FIG. 1A can reflect solar lights significantly at the infrared region having wavelengths within 800˜2500 nm. For the characteristics in reflecting the infrared, thus this solar control film layer 10A can be an infrared reflective solar control film.

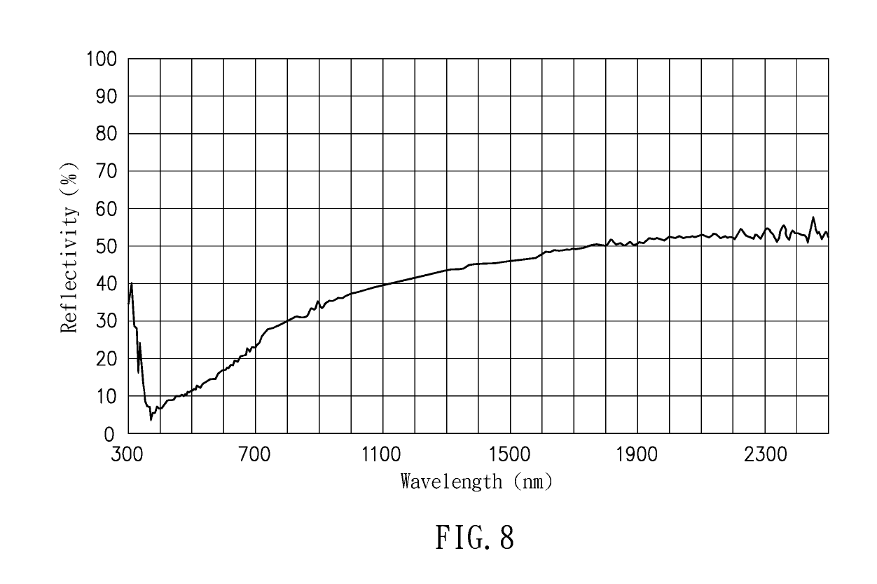

FIG. 8 is a schematic plot of a reflection spectrum for the solar control film layer of FIG. 2A. The horizontal axis of FIG. 8 stands for the wavelength, while the vertical axis thereof stands for the reflectivity. In this exemplary example, the solar control film layer 20A of FIG. 2A is taken to undergo a spectrum test. In this solar control film layer 20A, the first conductive layer 23 is the only conductive film. From the reflection spectrum shown in FIG. 8, the reflectivity is within 30˜50% for the wavelengths within 800˜2500 nm. It implies that the solar control film layer 20A of FIG. 2A can reflect solar lights at the infrared region having wavelengths within 800˜2500 nm. For the characteristics in reflecting the infrared, thus this solar control film layer 20A can be also an infrared reflective solar control film.

From the difference of the conductive films used in the solar control film layers (apparently, two Ag films in the solar control film layer 10A and one TiN film in solar control film layer 20A), it is found that the capability of the solar control film layer for reflecting infrared is highly related to the conductivity of the conductive film. This capability is also related to the thickness of the film. However, from FIG. 7 and FIG. 8, it is known that both the solar control film layer 10A of FIG. 1A and that 20A of FIG. 2A present the characteristics in reflecting infrared, and thus they both can provide effects of solar control.

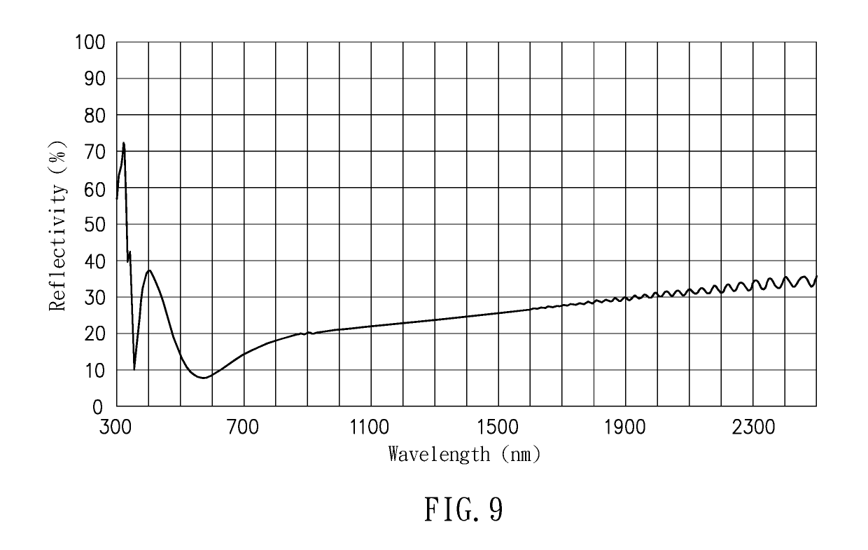

FIG. 9 is a schematic plot of a reflection spectrum for the solar control film produced by the method of FIG. 6. The horizontal axis of FIG. 9 stands for the wavelength, while the vertical axis thereof stands for the reflectivity. In this exemplary example, the solar control film layer 30A of FIG. 3A is taken to undergo a spectrum test. In this solar control film layer 30A, the first conductive layer 23 and the second conductive layer 35 are both conductive films. From the reflection spectrum shown in FIG. 9, the reflectivity is within 20˜30% for the wavelengths within 800˜2500 nm. It implies that the solar control film layer 30A of FIG. 3A can still reflect solar lights at the infrared region having wavelengths within 800˜2500 nm. For the characteristics in reflecting the infrared, thus this solar control film layer 30A can be an infrared reflective solar control film.

In summary, in comparison with the prior art that adopts a sputtering system to deposit the In-oxide dielectric layer, the solar control film and the method thereof provided by the present invention apply the arc-plasma coating process with lower cost but higher usage efficiency of coating targets to deposit the dielectric layers, and the material Ti is used to deposit the thin metal-oxide (TiO₂) films. Since the arc-plasma coating apparatus does not cost much relatively, and the usage efficiency of coating targets in the arc-plasma coating apparatus is usually better than that of conventional sputtering technique, thus the maintenance period for replacing the targets can be extended, the production can be faster, and the the respective production cost can be reduced.

Further, in comparison with the conventional infrared reflective solar control film that includes an In-oxide dielectric layer, since the indium (In) is widely and increasingly used in most of manufacturing processes in the electronic industry and hard to be obtained due to severe export policies of the source countries, the solar control film, the first dielectric layer of the present invention uses the common material Ti to form the thin metal-oxide (TiO₂) film, not the indium (In) to form the In-oxide dielectric layers. Thereupon, the risk in material shortage of the indium can be avoided, and also the production cost can be substantially reduced.

In addition, by comparing to the conventional solar control film that includes a metal-oxide coating film produced by sputtering, since a poisoning effect usually occurs at a target of a metal oxide during the sputtering process, thus in-process monitoring of this poisoning effect becomes important, and thereby the entire manufacturing difficulty would be raised. On the other hand, the dielectric layer of the solar control film produced in accordance with the present invention are formed by applying the arc-plasma coating process, and thus aforesaid shortcomings of the prior art in both the poisoning effect and the manufacturing difficulty can be substantially resolved.

Furthermore, in the present invention, the metal layers and the dielectric layers are alternately laminated onto each other so as to achieve the effect of solar control. In addition, in the present invention, the conductive layers deposited by the arc-plasma coating processes are used to substitute the conventional layers for being alternately laminated to each other with the dielectric layers, such that the effect of solar control can be also obtained.

While the present invention has been particularly shown and described with reference to a preferred embodiment, it will be understood by those skilled in the art that various changes in form and detail may be without departing from the spirit and scope of the present invention.

What is claimed is:

1. A method for manufacturing a solar control film, comprising the steps of:
applying an arc-plasma coating process to deposit a first dielectric layer on a soft substrate, the first dielectric layer containing Ti;
depositing a first metal layer on the first dielectric layer;
applying the arc-plasma coating process to deposit a second dielectric layer on the first metal layer, the second dielectric layer containing the Ti;
depositing a second metal layer on the second dielectric layer; and
applying the arc-plasma coating process to deposit a third dielectric layer on the second metal layer, the third dielectric layer containing the Ti.

2. The method for manufacturing a solar control film of claim 1, further including a step of using a transparent soft material for packaging.

3. The method for manufacturing a solar control film of claim 1, before the arc-plasma coating process to deposit the first dielectric layer, further including the steps of:
providing the soft substrate;
displacing the soft substrate into a chamber of an arc-plasma coating apparatus;
vacuuming the chamber; and
introducing an oxygen into the chamber.

4. The method for manufacturing a solar control film of claim 1, wherein the first metal layer contains Ag, and the second metal layer contains also the Ag.

5. The method for manufacturing a solar control film of claim 1, after the first metal layer is deposited on the first dielectric layer, further including a step of depositing a first protective layer on the first metal layer so as to sandwich the first protective layer between the first metal layer and the second dielectric layer.

6. The method for manufacturing a solar control film of claim 5, wherein the first protective layer contains the Ti.

7. The method for manufacturing a solar control film of claim 1, after the second metal layer is deposited on the second dielectric layer, further including a step of depositing a second protective layer on the second metal layer so as to sandwich the second protective layer between the second metal layer and the third dielectric layer.

8. The method for manufacturing a solar control film of claim 7, wherein the second protective layer contains the Ti.

9. A method for manufacturing a solar control film, comprising the steps of:
applying an arc-plasma coating process to deposit a first dielectric layer on a soft substrate, the first dielectric layer containing Ti;
applying the arc-plasma coating process to deposit a first conductive layer on the first dielectric layer; and
applying the arc-plasma coating process to deposit a second dielectric layer on the first conductive layer, the second dielectric layer containing the Ti.

10. The method for manufacturing a solar control film of claim 9, further including a step of using a transparent soft material for packaging.

11. The method for manufacturing a solar control film of claim 9, before the arc-plasma coating process to deposit the first dielectric layer, further including the steps of:
providing the soft substrate;
displacing the soft substrate into a chamber of an arc-plasma coating apparatus;
vacuuming the chamber; and
introducing an oxygen into the chamber.

12. The method for manufacturing a solar control film of claim 9, wherein the first conductive layer contains the TiN.

13. The method for manufacturing a solar control film of claim 9, wherein the step of applying the arc-plasma coating process to deposit the second dielectric layer on the first conductive layer includes the steps of:
applying the arc-plasma coating process to deposit a second conductive layer on the second dielectric layer; and
applying the arc-plasma coating process to deposit a third dielectric layer on the second conductive layer, the third dielectric layer containing the Ti.

14. The method for manufacturing a solar control film of claim 13, wherein the second conductive layer contains the TiN.

15. A solar control film, comprising:
a soft substrate;
a first dielectric layer, disposed on the soft substrate, formed by an arc-plasma coating process, containing Ti;
a first metal layer, disposed on the first dielectric layer;
a second dielectric layer, disposed on the first metal layer, formed by the arc-plasma coating process, containing the Ti;
a second metal layer, disposed on the second dielectric layer;
a third dielectric layer, disposed on the second metal layer, formed by the arc-plasma coating process, containing the Ti; and
an encapsulated layer, disposed on the third dielectric layer.

16. The solar control film of claim 15, wherein the first metal layer contains Ag, and the second metal layer contains also the Ag.

17. The solar control film of claim 15, further including:
a first protective layer, located between the first metal layer and the second dielectric layer; and
a second protective layer, located between the second metal layer and the third dielectric layer.

18. The solar control film of claim 17, wherein the first protective layer contains the Ti, and the second protective layer contains also the Ti.

19. A solar control film, comprising:
a soft substrate;
a first dielectric layer, disposed on the soft substrate, formed by an arc-plasma coating process, containing Ti;
a first conductive layer, disposed on the first dielectric layer;
a second dielectric layer, disposed on the first conductive layer, formed by the arc-plasma coating process, containing the Ti; and
an encapsulated layer, disposed on the second dielectric layer.

20. The solar control film of claim 19, further including:
a second conductive layer, disposed on the second dielectric layer; and
a third dielectric layer, disposed on the second conductive layer, formed by the arc-plasma coating process, containing the Ti.

21. The solar control film of claim 20, wherein the first conductive layer contains TiN, and the second conductive layer contains the TiN.

22. The solar control film of claim 20, wherein the first conductive layer is formed by the arc-plasma coating process, and the second conductive layer is also formed by the arc-plasma coating process.
